(19) United States
(12) Patent Application Publication
(10) Pub. No.: US 2012/0299020 A1
(43) Pub. Date: Nov. 29, 2012

(54) LED PACKAGE MODULE FOR LIGHTING

(76) Inventor: Wei-Jen CHEN, Taichung City (TW)

(21) Appl. No.: 13/170,422

(22) Filed: Jun. 28, 2011

(30) Foreign Application Priority Data
May 27, 2011 (TW) 100209652

(51) Int. Cl. H01L 27/15

(52) U.S. Cl. 257/88; 257/E27.12

(57) ABSTRACT

An LED package module for lighting includes a plurality of LED chips spacedly arranged on a hard substrate and a plurality of dome-shaped encapsulants arranged on the hard substrate in such a way that the encapsulants enclose the LED chips respectively. By means of the dome-shaped encapsulants, the light extracting rate of the LED chips is enhanced. On the surface of the hard substrate, no dam structure is needed; therefore, the amount of the encapsulant material used in the LED package module can be effectively saved.

### BACKGROUND OF THE INVENTION

1. Field of the Invention

The present invention relates generally to a light-emitting diode (hereinafter referred to as “LED”) package module and more particularly, to an LED package module for lighting, which adopts no dam structure.

2. Description of the Related Art

In a conventional LED package module, a shielding dam surrounding around an LED chip will be arranged on the substrate for enabling the encapsulant material to positively enclose the LED chip in the adhesive dispensing process. As shown in Taiwan patent no. M337827 titled “Package Structure of Light-emitting Diode” and Taiwan patent no. M332937 titled “Package structure of LED backlight module”, a recess for installation of an LED chip is formed on the surface of the substrate; therefore, the periphery wall defining the recess acts as the dam structure.

The conventional design of forming the dam structure on the surface of the substrate and filling the space surrounded by the dam structure with encapsulant material to positively enclose the LED chip will undoubtedly increase the material cost for building the substrate and the amount of the encapsulant material used, thereby increasing the manufacturing cost. In addition, the flat top surface of the encapsulant will adversely affect the light extracting rate of the LED chip due to a total internal reflection phenomenon. It can be seen that the conventional LED package module adopting the design of dam structure needs to be improved.

### SUMMARY OF THE INVENTION

The present invention has been accomplished in view of the above-noted circumstances. It is therefore one objective of the present invention to provide an LED package module for lighting, which can enhance the light extracting rate of the LED chips and can reduce the manufacturing cost thereof.

Another objective of the present invention is to provide an LED package module for lighting, which can be applied to various lamps, such that it has a great applicability in the field of lighting.

To achieve the above-mentioned objectives, the LED package module for lighting provided by the present invention comprises a hard substrate on which a plurality of LED chips and a plurality of dome-shaped encapsulants are arranged in such a way that the LED chips are spacedly mounted on the hard substrate and the dome-shaped encapsulants enclose the LED chips respectively. Therefore, the light extracting rate of the LED chips is thus enhanced. In addition, the conventional design of dam structure can be eliminated and the usage amount of the encapsulant material can be effectively saved, thereby effectively reducing the manufacturing cost.

Further, the hard substrate can be configured with various shapes, such as rectangular shape, square shape or circular shape, according to the lamp to which the LED package module is applied. For the hard substrate, several hard substrates having different thermal conductivities, such as glass fiber fabric laminate, aluminum plate or copper plate, can be used in coordination with the LED chips having a specific luminous efficiency to be used.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a cross-sectional view of an LED package module according to a first preferred embodiment of the present invention;

FIG. 2 is a top view of the LED package module of FIG. 1;

FIG. 3 is a top view an LED package module according to a second preferred embodiment of the present invention, and

FIG. 4 is a top view an LED package module according to a third preferred embodiment of the present invention.

### DETAILED DESCRIPTION OF THE INVENTION

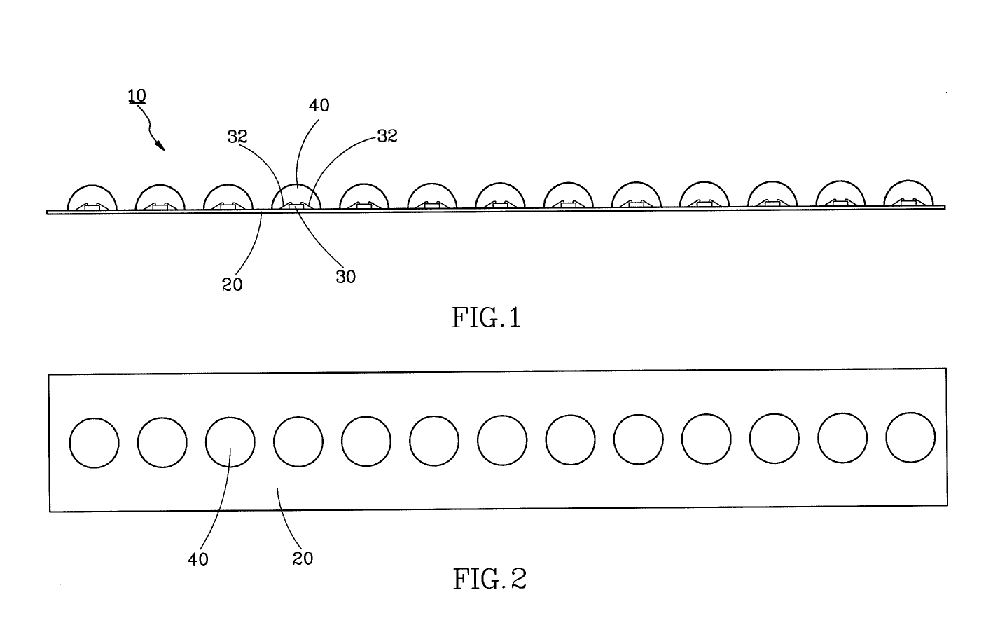

As shown in FIGS. 1-2, an LED package module, provided by a first preferred embodiment of the present invention and denoted by reference numeral 10, comprises a hard substrate 20, a plurality of LED chips 30 and a plurality of encapsulants 40.

In this preferred embodiment, the hard substrate 20 has a rectangular shape. For application in a tube lamp shaped like a conventional fluorescent tube, a number of the hard substrates 20 can be serially connected.

The LED chips 30 are spacedly mounted on the hard substrate 20 along a longitudinal direction of the hard substrate 20 at an equal interval. In addition, each LED chip 30 is electrically connected with the hard substrate 20 through bonding wires 32.

The encapsulants 40 are made from an encapsulant material containing a mixture of silicon resin and fluorescent powder, which is prepared by evenly dispersing the fluorescent powder in the silicon resin through a high speed mixer having an air bubble removing function. By means a dispenser, the encapsulant material is applied on LED chips 30 in such a way that each encapsulant 40 is dome-shapedly mounted on the hard substrate 20 and encloses one LED chip 30 and respective bonding wires 32.

As indicated above, by means of the dome surface of the dome-shaped encapsulant 40, the light extracting rate of the LED chips 30 of the present invention can be enhanced. In addition, the prior art design of dam structure can be omitted to decrease the total amount of the encapsulant material used so as to further reduce the manufacturing cost of the LED package module.

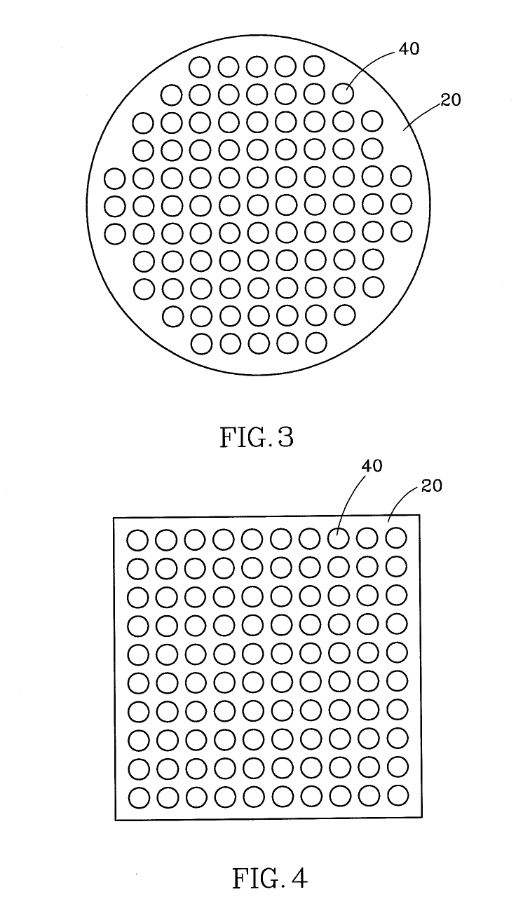

It will be appreciated that the shape of the hard substrate 20 is not limited to the above-mentioned rectangle. It can vary subject to the lamp structure to which the LED package module 10 is applied. For example, the hard substrate 20 may have a circular shape as shown in FIG. 3 for applying thereto a recessed lamp. Alternatively, the hard substrate 20 may have a square shape as shown in FIG. 4 for applying thereto a street lamp. Further, according to the luminous efficiency of the LED chips 30 to be used, a hard substrate having a specific thermal conductivity can be used. For example, a glass fiber fabric laminate having a thermal conductivity of 0.36 W/mK, an aluminum plate having a thermal conductivity of 237 W/mK, or a copper plate having a thermal conductivity of 401 W/mK can be used as the hard substrate 20 of the present invention.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An LED package module for lighting, comprising:
a hard substrate;
a plurality of LED chips spacedly mounted on the hard substrate, and a plurality of dome-shaped encapsulants mounted on the hard substrate in a way that the dome-shaped encapsulants enclose the LED chips respectively.

2. The LED package module as claimed in claim 1, wherein the hard substrate has a rectangular, square or circular shape.

3. The LED package module as claimed in claim 2, wherein the hard substrate is selected from the group consisting of a glass fiber fabric laminate, an aluminum plate and a copper plate.

4. The LED package module as claimed in claim 1, wherein the hard substrate is selected from the group consisting of a glass fiber fabric laminate, an aluminum plate and a copper plate.

5. The LED package module as claimed in claim 1, wherein the encapsulants are made from a material containing a mixture of silicon resin and fluorescent powder.
